(19) United States
(12) Patent Application Publication
(10) Pub. No.: US 2009/0152680 A1
(43) Pub. Date: Jun. 18, 2009

(54) ELECTROSTATIC DISCHARGE PROTECTION FOR BIPOLAR SEMICONDUCTOR CIRCUITRY

(75) Inventor: Steven H. Voldman, South Burlington, VT (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/958,558

(22) Filed: Dec. 18, 2007

(51) Int. Cl. H01L 27/082

(52) U.S. Cl. 257/568; 257/E27.053

(57) ABSTRACT

Multiple emitter-base regions arc formed on a single contiguous collector. The multiple emitter-base regions are cascoded such that the base of one emitter-base region is directly wired to the emitter of an adjacent emitter-base region. An electrostatic discharge (ESD) protection unit, comprising a single collector and multiple emitter-base regions, provides protection against an ESD event of one type, i.e., a positive or negative voltage surge. The inventive ESD protection structure comprises a parallel connection of two ESD protection units, each providing a discharge path for electrical charges of opposite types, and provides ESD protection for both types of voltage swing in the circuit.

### FIELD OF THE INVENTION

The present invention relates to a semiconductor structures and circuits, and particularly to semiconductor structures and circuits for an electrostatic discharge protection for bipolar semiconductor circuitry including radio frequency (RF) power amplifiers.

### BACKGROUND OF THE INVENTION

An electrostatic discharge (ESD) event can occur in a semiconductor chip when a charged conductor (including the human body) discharges through the semiconductor chip. An electrostatic charge may accumulate on a human body, for example, when one walks on a carpet. Contact of a body part, e.g., a finger, to a device containing a semiconductor chip causes the body to discharge, possibly causing damage to the semiconductor device. A similar discharge may occur from a charged conductive object, such as a metallic tool. Static charge may also accumulate on a semiconductor chip through handling or contact with packaging materials or work surfaces.

Such an ESD event can cause failure of components in a semiconductor chip through current overloading or reverse biasing. For example, the propagation of electrical charges through a bipolar transistor may cause an emitter-base junction to become heavily reverse biased, triggering a functional failure of the bipolar transistor in an ESD event. The voltage required for failure is linearly proportional to the area of the emitter of the bipolar transistor. Consequently, the potential for failure increases as circuitry, and therefore the area of the emitter, becomes smaller.

Radio frequency (RF) power amplifiers employing silicon germanium heterojunction bipolar transistors have a large swing in the signal both for positive voltages and negative voltages, typically up to positive 5V and negative 5V. Such RE power amplifiers typically employ dual well bipolar complementary metal oxide semiconductor (BiCMOS) technology. However, electrostatic discharge circuits currently known in the art in the BiCMOS technology are inadequate for providing sufficient protection against ESD events for such RF power amplifiers.

While multi-emitter silicon germanium bipolar transistors having multiple emitter-base regions in parallel connection have been proposed to provided enhanced protection against ESD events, such a device tends to occupy a large area, while improvement in the protection is not substantial. Employing separate devices to form an ESD protection circuit introduces parasitic interaction between collectors as well as increase in the ESD circuit area.

In view of the above, there exists a need for a compact and efficient circuit and a structure thereof for protection against electrostatic discharge events employing bipolar transistors, which may be employed in radio frequency (RF) power amplifiers employing BiCMOS technology.

### SUMMARY OF THE INVENTION

The present invention addresses the needs described above by providing a compact bipolar semiconductor structure and a circuit thereof for providing protection against electrostatic discharge events in circuits with large positive and negative voltage swings.

In the present invention, multiple emitter-base regions are formed on a single contiguous collector. The multiple emitter-base regions are cascoded such that the base of one emitter-base region is directly wired to the emitter of an adjacent emitter-base region. An electrostatic discharge (ESD) protection unit, comprising a single collector and multiple emitter-base regions, provides protection against an ESD event of one type, i.e., a positive or negative voltage surge. The inventive ESD protection structure comprises a parallel connection of two ESD protection units, each providing a discharge path for electrical charges of opposite types, and provides ESD protection for both types of voltage swing in the circuit.

According to an aspect of the present invention, a semiconductor structure is provided, which comprises a first electrostatic discharge (ESD) protection structure and a second ESD protection structure that are connected in a parallel connection between a signal path and ground.

The first ESD protection structure comprises:

a first collector having a doping of a first conductivity type and located in a semiconductor substrate;

a plurality of first emitter-base regions abutting the first collector, wherein each of the first emitter-base regions comprises an emitter having a doping of the first conductivity type and a base having a doping of a second conductivity type, wherein the second conductivity type is the opposite of the first conductivity type;

a first interconnect structure connecting a base of one of the plurality of the first emitter-base regions to the ground;

a second interconnect structure connecting an emitter of another of the plurality of the first emitter-base regions to the signal path; and

at least one third interconnect structure connecting a base of each of the plurality of the first emitter-base regions that is not connected to the first interconnect structure to an emitter of another of the plurality of the first emitter-base regions so that all of the first emitter-base regions are cascoded.

The second ESD protection structure comprises:

a second collector having a doping of the first conductivity type and located in the semiconductor substrate and electrically isolated from the first collector;

a plurality of second emitter-base regions abutting the second collector, wherein each of the second emitter-base regions comprises an emitter having a doping of the first conductivity type and a base having a doping of a second conductivity type;

a third interconnect structure connecting a base of one of the plurality of the second emitter-base regions to the signal path;

a fourth interconnect structure connecting an emitter of another of the plurality of the second emitter-base regions to the ground; and

at least one sixth interconnect structure connecting a base of each of the plurality of the first emitter-base regions that is not connected to the fourth interconnect structure to an emitter of another of the plurality of the second emitter-base regions so that all of the second emitter-base regions are cascoded.

According to another aspect of the present invention, a semiconductor circuit is provided, which comprises a first electrostatic discharge (ESD) protection circuit and a second ESD protection circuit that are connected in a parallel connection between a signal path and ground.

The first ESD protection circuit comprises a cascoded plurality of primary bipolar transistors of one transistor type including first through n-th primary bipolar transistors, wherein n is a positive integer equal to or greater than 2, wherein the transistor type is selected from an npn type and a pnp type, wherein a base of the first primary bipolar transistor is connected to ground, wherein an emitter of the n-th primary bipolar transistor is connected to the signal path, and wherein a base of an i-th primary bipolar transistor is connected to an emitter of an (i-1)-th primary bipolar transistor for each value of i between and including 2 and n, and wherein all collectors of the cascoded plurality of primary bipolar transistors are electrically tied.

The second ESD protection circuit comprises a cascoded plurality of complementary bipolar transistors of the transistor type including first through m-th complementary bipolar transistors, wherein m is a positive integer equal to or greater than 2, wherein a base of the first complementary bipolar transistor is connected to the signal path, wherein an emitter of the m-th complementary bipolar transistor is connected to the ground, and wherein a base of a k-th complementary bipolar transistor is connected to an emitter of a (k-1)-th complementary bipolar transistor for each value of k between and including 2 and n, and wherein all collectors of the cascoded plurality of complementary bipolar transistors are electrically tied.

### BRIEF DESCRIPTION OF THE DRAWINGS

FIG. 1 is a first exemplary semiconductor circuit according to a first embodiment of the present invention.

FIG. 2 is a second exemplary semiconductor circuit according to a second embodiment of the present invention.

FIG. 3 is a first exemplary ESD protection structure that forms a part of an exemplary semiconductor structure according to the present invention.

FIG. 4 is a second exemplary ESD protection structure that forms another part of the exemplary semiconductor structure according to the present invention.

### DETAILED DESCRIPTION OF THE INVENTION

As stated above, the present invention relates to semiconductor structures and circuits for an electrostatic discharge protection for bipolar semiconductor circuitry including radio frequency (RF) power amplifiers, which are now described in detail with accompanying figures. It is noted that like and corresponding elements are referred to by like reference numerals.

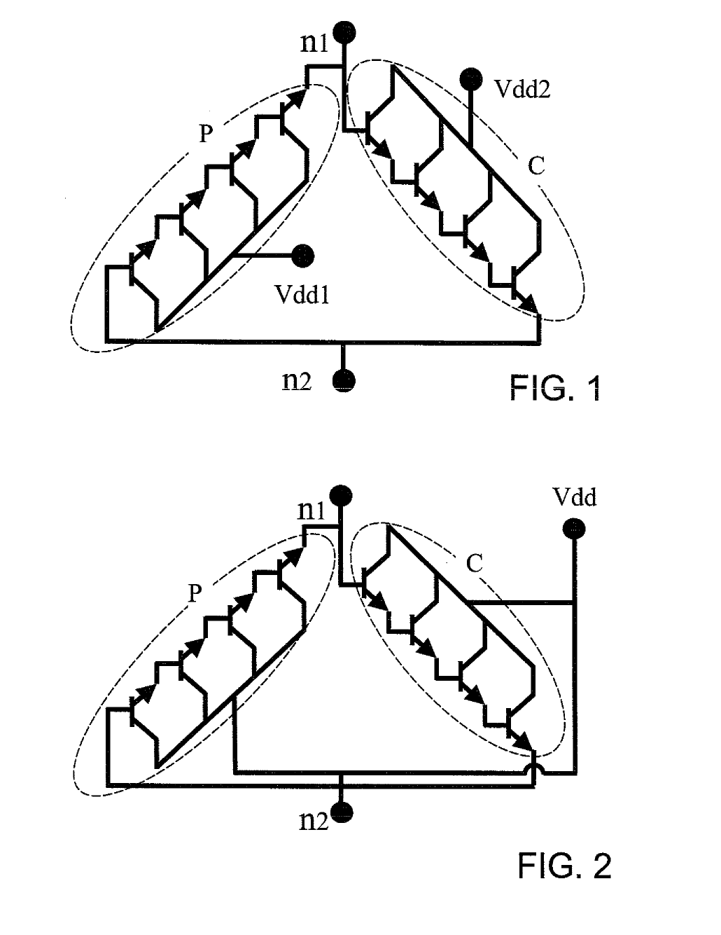

According to an aspect of the present invention, semiconductor circuits for protection against electrostatic discharge (ESD) events are disclosed. Referring to FIG. 1, a first exemplary semiconductor circuit according to a first embodiment of the present invention comprises a cascoded plurality of primary bipolar transistors P, a cascoded plurality of complementary bipolar transistors C, a first signal node n1, a second signal node n2, a first power supply node, Vdd1, which is connected to collectors of the primary bipolar transistors, and a second power supply node, Vdd2, which connected to collectors of the complementary bipolar transistors. The first exemplary semiconductor circuit is an electrostatic discharge (ESD) protection circuit that provides a discharge path during an ESD event. Preferably, the first signal node n1 is a signal path having a positive and negative voltage swing. In case the first exemplary semiconductor circuit provides electrostatic discharge protection to a circuit containing radio frequency power amplifiers, the voltage on first signal node n1 typically ranges from −5 V to +5 V. Preferably, the second signal node n2 is connected to ground.

While the present invention is described with npn type bipolar transistors, one skilled in the art would readily construct an equivalent version of the first exemplary semiconductor circuit constructed with pnp type bipolar transistors and reversing polarity of voltages on various nodes. Such obvious variations on the first exemplary semiconductor circuit are explicitly contemplated herein.

If the cascoded plurality of primary bipolar transistors P comprises npn transistors as shown in FIG. 1, a positive voltage is supplied to the first power supply node Vdd1. Likewise, if the cascoded plurality of complementary bipolar transistors C comprises npn transistors, a positive voltage is supplied to the second power supply node Vdd2. In this case, not necessarily but preferably, the voltage at the first power supply node Vdd1 and the voltage at the second power supply node Vdd2 are a most positive available voltage on the circuit which the first exemplary semiconductor circuit intends to protect from ESD events.

If the cascoded plurality of primary bipolar transistors P comprises pnp transistors, a negative voltage is supplied to the first power supply node Vdd1. Likewise, if the cascoded plurality of complementary bipolar transistors C comprises pnp transistors, a negative voltage is supplied to the second power supply node Vdd2. In this case, not necessarily but preferably, the voltage at the first power supply node Vdd1 and the voltage at the second power supply node Vdd2 are a most negative available voltage on the circuit which the first exemplary semiconductor circuit intends to protect from ESD events.

The cascoded plurality of primary bipolar transistors P comprises first through n-th primary bipolar transistors, in which n is a positive integer equal to or greater than 2. The first primary bipolar transistor refers to the primary bipolar transistor of which the base is directly connected to the second signal node n2, which is preferably grounded. The n-th primary bipolar transistor refers to the primary bipolar transistor of which the emitter is directly connected to the first signal node n1, which is connected to the signal path. A base of an i-th primary bipolar transistor is connected to an emitter of an (i-1)-th primary bipolar transistor for each value of i between and including 2 and n. All collectors of the cascoded plurality of primary bipolar transistors P are electrically tied to the first power supply node Vdd1. Preferably, all the collectors of the cascoded plurality of primary bipolar transistors P are integrally formed as a single contiguous collector constituting a single device component.

The cascoded plurality of complementary bipolar transistors C comprises first through m-th complementary bipolar transistors, in which m is a positive integer equal to or greater than 2. The first complementary bipolar transistor refers to the complementary bipolar transistor of which the base is directly connected to the first signal node n1, which is connected to the signal path. The m-th complementary bipolar transistor refers to the complementary bipolar transistor of which the emitter is directly connected to the second signal node n2, which is preferably grounded. A base of a k-th complementary bipolar transistor is connected to an emitter of a (k-1)-th complementary bipolar transistor for each value of k between and including 2 and m. All collectors of the cascoded plurality of complementary bipolar transistors C are electrically tied to the second power supply node Vdd2. Preferably, all the collectors of the cascoded plurality of complementary bipolar transistors C are integrally formed as a single contiguous collector constituting a single device component.

In case an ESD event triggers a high negative voltage at the first node n1, the cascoded plurality of primary bipolar transistors P provides a current path for discharge of the negative charge associated with the highly negative voltage. In case an ESD event triggers a high positive voltage at the first node n1, the cascoded plurality of complementary bipolar transistors C provides a current path for discharge of the positive charge associated with the highly positive voltage. Thus, the pair of the cascoded plurality of primary bipolar transistors P and the cascoded plurality of complementary bipolar transistors C in a parallel connection between the first signal node n1 and the second signal node n2 provides protection against ESD events that trigger a large instantaneous charge at the first signal node n1 by providing a conductive discharge path to the second signal node n2, which is typically connected to ground.

Referring to FIG. 2, a second exemplary semiconductor circuit according to a second embodiment of the present invention comprises a cascoded plurality of primary bipolar transistors P, a cascoded plurality of complementary bipolar transistors C, a first signal node n1, and a second signal node n2 as in the first exemplary semiconductor circuit. However, a power supply node Vdd is connected to collectors of the primary bipolar transistors and the complementary bipolar transistors, thus replacing the first power supply node, Vdd1 and the second power supply node, Vdd2 of the first exemplary semiconductor circuit. The second exemplary semiconductor circuit is an electrostatic discharge (ESD) protection circuit that provides a discharge path during an ESD event and performs in the same manner as the first exemplary semiconductor circuit.

According to another aspect of the present invention, a semiconductor structure for protection against electrostatic discharge (ESD) is provided, which comprises a first ESD protection structure and a second ESD protection structure that are connected in a parallel connection between a signal path and ground. An equivalent circuit for the semiconductor structure may be the first exemplary semiconductor circuit or the second exemplary semiconductor circuit described above. The signal path corresponds to the first signal node n1, and the ground corresponds to the second signal node n2. The first ESD protection structure and the second ESD protection structure are formed on the same semiconductor substrate, and preferably within the same semiconductor chip.

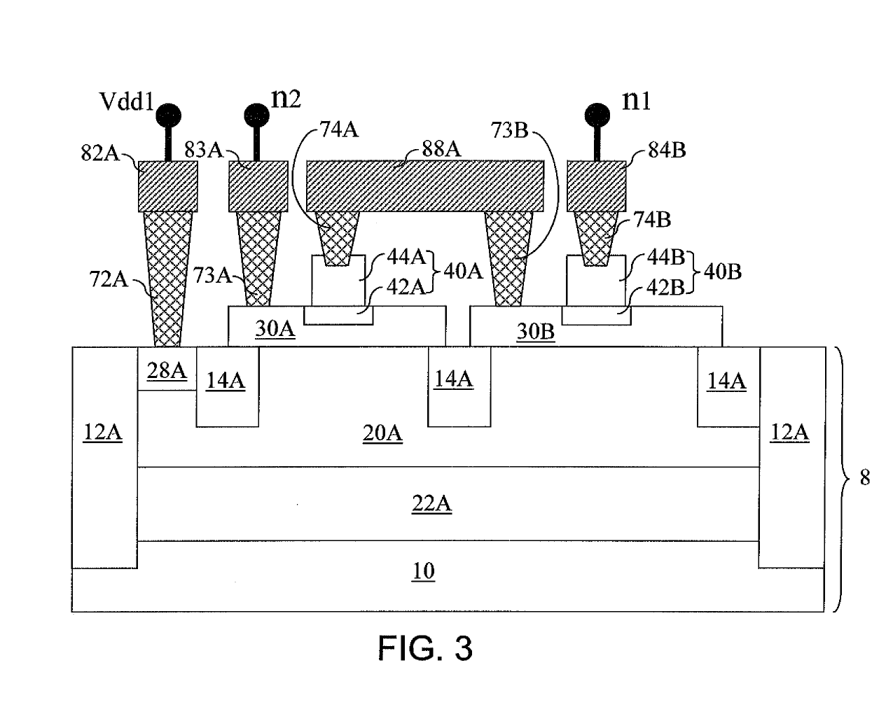

Referring to FIG. 3, a vertical cross-sectional view of an exemplary first ESD protection structure according to the present invention is shown along with schematic representations to connections to a first signal node n1, a second signal node n2, and a first power supply node Vdd1, each of which functionally corresponds to the same element in the first exemplary semiconductor circuit of FIG. 1 having the same name. The exemplary first ESD protection structure comprises a semiconductor substrate 8 comprising a substrate layer 10, first deep trench isolation structures 12A, first shallow trench isolation structures 14A, a first subcollector 22A, a first collector 20A, and a first collector reachthrough 28A.

The first subcollector 22A has a doping of a first conductivity type, which may be p-type or n-type, and is formed by implantation of dopants of the first conductivity type into the semiconductor substrate 8. The first subcollector 22A is heavily doped to reduce resistance, and has a dopant concentration from about 1.0×10¹⁹/cm³ to about 1.0×10²¹/cm³. The first deep trench isolation structures 12A are formed by forming deep trenches in the semiconductor substrate 8, and filling them with an insulator material such as silicon oxide and undoped polysilicon. The first shallow trench isolation structures 14A are formed by forming shallow trenches and filling them with an insulator material such as silicon oxide and/or silicon nitride. Typically, the first deep trench isolation structures 12A extend beneath a bottom surface of the first subcollector 22A. The bottom surfaces of the first shallow trench isolation structures 14A are located above the depth of the top surface of the first subcollector 22A. Thus, the first collector 20A is of unitary construction, i.e., in one contiguous piece.

The first collector 20A has a doping of the first conductivity type. The first collector reachthrough 28A also has a doping of the first conductivity type, and typically has a higher dopant concentration than the first collector 20A to reduce its resistance.

In general, a first ESD semiconductor structure comprises a plurality of first emitter-base regions that are formed directly on the first collector 20A. Each of the first emitter-base regions comprises an emitter having a doping of the first conductivity type and a base having a doping of a second conductivity type, which is the opposite of the first conductivity type. For example, if the first conductivity type is n-type, the second conductivity type is p-type, and vice versa. A first interconnect structure connects a base of one of the plurality of the first emitter-base regions to a second signal node, which is connected to ground. A second interconnect structure connects an emitter of another of the plurality of the first emitter-base regions to the first signal node, which is connected to a signal path At least one third interconnect structure connects a base of each of the plurality of the first emitter-base regions that is not connected to the first interconnect structure to an emitter of another of the plurality of the first emitter-base regions so that all of the first emitter-base regions are cascoded.

In the case of the exemplary first ESD semiconductor structure in FIG. 3, the first emitter-base regions comprise an “emitter-base region A” and an “emitter-base region B.” It is noted herein that an alphabetical suffix to a device component herein refers to an instance of such a device component, and that the alphabetical suffix is employed for the purpose of differentiating multiple instances of the device component. Thus, each of the “emitter-base region A” and the “emitter-base region B” is a distinct emitter-base region. The emitter-base region A comprises an “emitter A” 40A that comprises a “polycrystalline emitter A” 44A which comprises a polycrystalline semiconductor material having a doping of the first conductivity type and a “single crystalline emitter A” 42A which comprises a single crystalline semiconductor material having a doping of the first conductivity type. The emitter-base region A also comprises a “base A” 30A that comprises a single crystalline semiconductor material having a doping of the second conductivity type. Likewise, the emitter-base region B comprises an “emitter B” 40B that comprises a “polycrystalline emitter B” 44B which comprises a polycrystalline semiconductor material having a doping of the first conductivity type and a “single crystalline emitter B” 42B which comprises a single crystalline semiconductor material having a doping of the first conductivity type. The emitter-base region B also comprises a “base B” 30B that comprises a single crystalline semiconductor material having a doping of the second conductivity type. A typical material for the polycrystalline emitter A (44A) and the polycrystalline emitter B (44B) is polysilicon. A typical material for the base A (30A) and base B (30B) is a silicon germanium alloy.

A base contact via 73A and a base contact metal line 83A collectively constitute a first interconnect structure that connects the base A (30A) of the emitter-base region A to the second signal node n2, which is connected to ground. An emitter contact via 74B and an emitter contact metal line 84B collectively constitute a second interconnect structure that connects the emitter B (40B) of the emitter-base region B to the first signal node, which is connected to the signal path. The base B (30B) of the emitter-base region B, which is not connected to the first interconnect structure (73A, 83A), is connected to the emitter A (40A) of the emitter-base region A by a third interconnect structure. The third interconnect structure comprises a contact via 73B to the base B (30B) of the emitter-base region B, a metal line 88A, and another contact via 74A to the emitter A (40A) of the emitter-base region A. Thus, all of the first emitter-base regions including the emitter-base region A and the emitter-base region B are cascoded.

Yet another contact via 72A directly contacting the first collector reachthrough 28A and another metal line 82A contacting the yet another contact via 72A provide an electrical connection between the first collector reachthrough 28A and the first supply voltage node Vdd1 to electrically bias the exemplary first ESD semiconductor structure and render it operational in a forward bias mode. The exemplary first ESD semiconductor structure functions as the cascoded plurality of primary bipolar transistors P in FIGS. 1 and 2. Note that use of a common supply voltage node Vdd instead of two separate supply voltage nodes transforms the first exemplary semiconductor circuit into the second exemplary semiconductor circuit.

The exemplary first ESD semiconductor structure may be readily modified to include more than two emitter-base regions as described above for general cases, in which multiple cascoding is effected by connecting each base that is not connected to the second signal node n2 to an emitter of an adjacent emitter-base region as described by the cascoded plurality of primary bipolar transistors P in FIGS. 1 and 2.

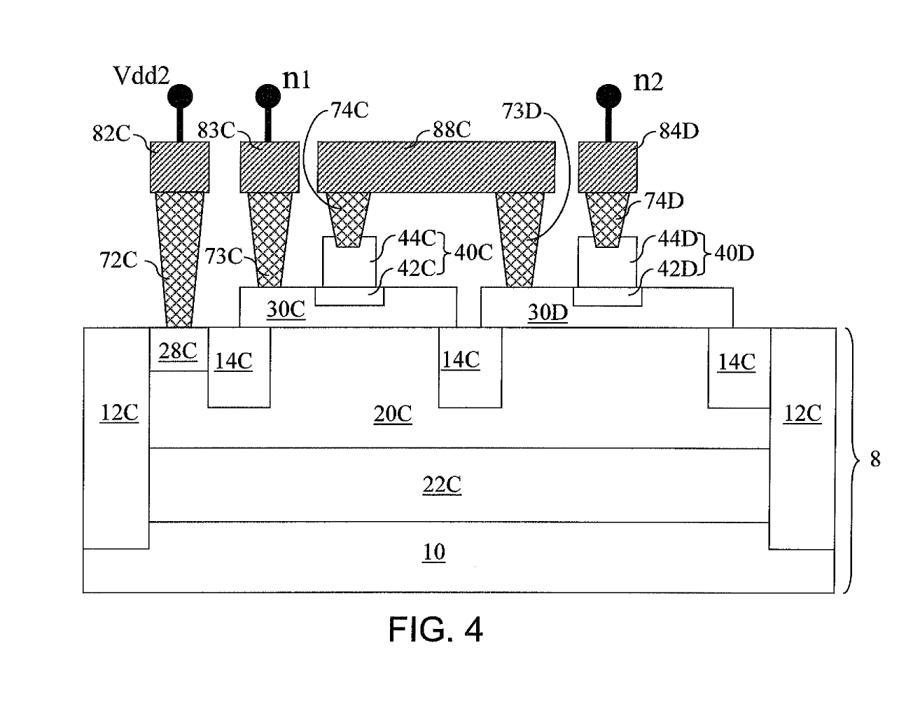

Referring to FIG. 4, a vertical cross-sectional view of an exemplary second ESD protection structure according to the present invention is shown along with schematic representations to connections to a first signal node n1, a second signal node n2, and a second power supply node Vdd1, each of which functionally corresponds to the same element in the first exemplary semiconductor circuit of FIG. 1 having the same name. The exemplary second ESD protection structure comprises a semiconductor substrate 8 comprising the substrate layer 10, second deep trench isolation structures 12C, second shallow trench isolation structures 14C, a second subcollector 22C, a second collector 20C, and a second collector reachthrough 28C.

The second subcollector 22C has a doping of the first conductivity type, which is the same conductivity type of the doping of the first subcollector 22A of FIG. 3, and is formed by implantation of dopants of the first conductivity type into the semiconductor substrate 8. The second subcollector 22C is heavily doped to reduce resistance, and has a dopant concentration from about 1.0×10¹⁹/cm³ to about 1.0×10²¹/cm³. The first and second subcollectors (22A, 22C) may be formed at a same processing step. The second deep trench isolation structures 12C are formed by forming deep trenches in the semiconductor substrate 8, and filling them with an insulator material such as silicon oxide and undoped polysilicon. The first and second deep trench isolation structures (12A, 12C) may be formed at a same processing step. The second shallow trench isolation structures 14C are formed by forming shallow trenches and filling them with an insulator material such as silicon oxide and/or silicon nitride. The first and second shallow trench isolation structures (14A, 14C) may be formed at a same processing step. Typically, the second deep trench isolation structures 12C extend beneath a bottom surface of the second subcollector 22C. The bottom surfaces of the second shallow trench isolation structures 14C are located above the depth of the top surface of the second subcollector 22C. Thus, the second collector 20C is of unitary construction, i.e., in one contiguous piece.

The second collector 20C has a doping of the first conductivity type. The second collector reachthrough 28C also has a doping of the first conductivity type, and typically has a higher dopant concentration than the second collector 20C to reduce its resistance.

In general, a second ESD semiconductor structure comprises a plurality of second emitter-base regions that are formed directly on the second collector 20C. Each of the second emitter-base regions comprises an emitter having a doping of the first conductivity type and a base having a doping of the second conductivity type. A fourth interconnect structure connects a base of one of the plurality of the second emitter-base regions to the first signal node, which is connected to the signal path. A fifth interconnect structure connects an emitter of another of the plurality of the second emitter-base regions to the second signal node, which is connected to ground. At least one sixth interconnect structure connects a base of each of the plurality of the second emitter-base regions that is not connected to the fourth interconnect structure to an emitter of another of the plurality of the second emitter-base regions so that all of the second emitter-base regions are cascoded.

In the case of the exemplary second ESD semiconductor structure in FIG. 4, the second emitter-base regions comprise an “emitter-base region C” and an “emitter-base region D.” The emitter-base region C comprises an “emitter C” 40C that comprises a “polycrystalline emitter C” 44C which comprises a polycrystalline semiconductor material having a doping of the first conductivity type and a “single crystalline emitter C” 42C which comprises a single crystalline semiconductor material having a doping of the first conductivity type. The emitter-base region C also comprises a “base C” 30C that comprises a single crystalline semiconductor material having a doping of the second conductivity type. Likewise, the emitter-base region D comprises an “emitter D” 40D that comprises a “polycrystalline emitter D” 44D which comprises a polycrystalline semiconductor material having a doping of the first conductivity type and a “single crystalline emitter D” 42D which comprises a single crystalline semiconductor material having a doping of the first conductivity type. The emitter-base region D also comprises a “base D” 30D that comprises a single crystalline semiconductor material having a doping of the second conductivity type. A typical material for the polycrystalline emitter C (44C) and the polycrystalline emitter D (44D) is polysilicon. A typical material for the base C (30C) and base D (30D) is a silicon germanium alloy.

A base contact via 73C and a base contact metal line 83C collectively constitute a fourth interconnect structure that connects the base C (30C) of the emitter-base region A to the first signal node n1, which is connected to the signal path. An emitter contact via 74D and an emitter contact metal line 84D collectively constitute a fourth interconnect structure that connects the emitter D (40D) of the emitter-base region D to the second signal node, which is connected to ground. The base D (30D) of the emitter-base region D, which is not connected to the fourth interconnect structure (73C, 83C), is connected to the emitter C (40C) of the emitter-base region C by a sixth interconnect structure. The third interconnect structure comprises a contact via 73B to the base B (30B) of the emitter-base region B, a metal line 88A, and another contact via 74A to the emitter A (40A) of the emitter-base region A. Thus, all of the second emitter-base regions including the emitter-base region C and the emitter-base region D are cascoded.

Yet another contact via 72C directly contacting the second collector reachthrough 28C and another metal line 82C contacting the yet another contact via 72C provide an electrical connection between the second collector reachthrough 28C and the second supply voltage node Vdd2 to electrically bias the exemplary second ESD semiconductor structure and render it operational in a forward bias mode. The exemplary second ESD semiconductor structure functions as the cascoded plurality of complementary bipolar transistors P in FIGS. 1 and 2. Note that use of a common supply voltage node Vdd instead of two separate supply voltage nodes transforms the first exemplary semiconductor circuit into the second exemplary semiconductor circuit.

The exemplary second ESD semiconductor structure may be readily modified to include more than two emitter-base regions as described above for general cases, in which multiple cascoding is effected by connecting each base that is not connected to the first signal node n1 to an emitter of an adjacent emitter-base region as described by the cascoded plurality of complementary bipolar transistors C in FIGS. 1 and 2.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A semiconductor structure comprising a first electrostatic discharge (ESD) protection structure and a second ESD protection structure that are connected in a parallel connection between a signal path and ground,
wherein said first ESD protection structure comprises:
a first collector having a doping of a first conductivity type and located in a semiconductor substrate;
a plurality of first emitter-base regions abutting said first collector, wherein each of said first emitter-base regions comprises an emitter having a doping of said first conductivity type and a base having a doping of a second conductivity type, wherein said second conductivity type is the opposite of said first conductivity type;
a first interconnect structure connecting a base of one of said plurality of said first emitter-base regions to said ground;
a second interconnect structure connecting an emitter of another of said plurality of said first emitter-base regions to said signal path; and
at least one third interconnect structure connecting a base of each of said plurality of said first emitter-base regions that is not connected to said first interconnect structure to an emitter of another of said plurality of said first emitter-base regions so that all of said first emitter-base regions are cascoded, and
wherein said second ESD protection structure comprises:
a second collector having a doping of said first conductivity type and located in said semiconductor substrate and electrically isolated from said first collector;
a plurality of second emitter-base regions abutting said second collector, wherein each of said second emitter-base regions comprises an emitter having a doping of said first conductivity type and a base having a doping of a second conductivity type;
a third interconnect structure connecting a base of one of said plurality of said second emitter-base regions to said signal path;
a fourth interconnect structure connecting an emitter of another of said plurality of said second emitter-base regions to said ground; and
at least one sixth interconnect structure connecting a base of each of said plurality of said first emitter-base regions that is not connected to said fourth interconnect structure to an emitter of another of said plurality of said second emitter-base regions so that all of said second emitter-base regions are cascoded.

2. A semiconductor circuit comprising a first electrostatic discharge (ESD) protection circuit and a second ESD protection circuit that are connected in a parallel connection between a signal path and ground,
wherein said first ESD protection circuit comprises a cascoded plurality of primary bipolar transistors of one transistor type including first through n-th primary bipolar transistors, wherein n is a positive integer equal to or greater than 2, wherein said transistor type is selected from an npn type and a pnp type, wherein a base of said first primary bipolar transistor is connected to ground, wherein an emitter of said n-th primary bipolar transistor is connected to said signal path, and wherein a base of an i-th primary bipolar transistor is connected to an emitter of an (i-1)-th primary bipolar transistor for each value of i between and including 2 and n, and wherein all collectors of said cascoded plurality of primary bipolar transistors are electrically tied, and
wherein said second ESD protection circuit comprises a cascoded plurality of complementary bipolar transistors of said transistor type including first through m-th complementary bipolar transistors, wherein m is a positive integer equal to or greater than 2, wherein a base of said first complementary bipolar transistor is connected to said signal path, wherein an emitter of said m-th complementary bipolar transistor is connected to said ground, and wherein a base of a k-th complementary bipolar transistor is connected to an emitter of a (k-1)-th complementary bipolar transistor for each value of k between and including 2 and n, and wherein all collectors of said cascoded plurality of complementary bipolar transistors are electrically tied.
